(19) United States
(12) Patent Application Publication
(10) Pub. No.: US 2002/0110189 A1
(43) Pub. Date: Aug. 15, 2002

(54) Method and apparatus for a frequency agile variable bandwidth transceiver

(76) Inventors: Slim Salah Souissi, San Diego, CA (US); Michael Scott Andrews, Escondido, CA (US)

Correspondence Address: COUDERT BROTHERS, 600 Beach Street, 3rd Floor, San Francisco, CA, 94109, US

(21) Appl. No.: 09/929,252

(22) Filed: Aug. 13, 2001

Related U.S. Application Data
(60) Provisional application No. 60/224,945, filed on Aug. 11, 2000.
(60) Provisional application No. 60/231,675, filed on Sep. 11, 2000.

(51) Int. Cl. H03K 5/159; H03H 7/30; H03H 7/40; H04B 1/10

(52) U.S. Cl. 375/235; 375/350

(57) ABSTRACT

A new radio frequency transceiver architecture comprises a combination of direct digital synthesis and digital control functions to control dual switched capacitor filters in order to perform radio frequency conversion directly to and from baseband.

This application claims the benefit of U.S. Provisional Application No. 60/224,945 filed Aug. 11, 2000 and U.S. Provisional Application No. 60/231,675 filed Sep. 11, 2000.

### BACKGROUND OF THE INVENTION

Current generation mobile transceivers do not have programmable or adaptive flexibility to operate multiple air standards (i.e., a multi-mode, multi-band radio architecture). Various techniques are known in the art for achieving dual and even tri-band radio transceivers for mobile applications. The shortcomings of the current approaches are many-fold. For example, there is often a duplication of front-end hardware (low-noise amplifiers, oscillators, mixers, and power amplifiers) in order to obtain a multi-band radio. Secondly, sensitivity is often fixed within a given standard's air interface solution. With this problem, it is possible to destroy an amplifier when the wrong air interface is programmed into the mobile radio, and it is close to a base transceiver station (BTS). The third shortcoming is that special and costly external IF filters, such as surface acoustic wave (SAW) type or ceramic filters, are used to do bandwidth limiting in the down conversion chain in order to adequately reject adjacent channels. The fourth shortcoming is that, with many multi-frequency oscillator approaches, transmitter bleed-through occurs in the receiver for many types of single integrated circuit transceiver designs. As a result, these conventional methods for providing a multi-band transceiver must be fabricated on multiple integrated circuits in order to avoid the transmitter bleed-through problem.

In radio frequency transceiver design, it is common to utilize already available transmitter and receiver elements specific for the mode and band of interest. Oscillator design appears to be the most advanced in terms of programmability and hardware re-use. Direct digital synthesizers (DDS's) functioning as programmable oscillators (e.g., devices manufactured by Analog Devices and Texas Instruments) are used in a number of modern transceiver designs. Presently, this and automatic gain control appear to be the only purely programmable elements in the radio frequency transceiver front-end.

The problem to be solved is to design an efficient radio transceiver architecture that can be programmed or adapted to multiple air standards.

### SUMMARY OF THE INVENTION

The present invention consists of an architecture for a complete, programmable, mobile radio data transceiver that has frequency agility, variable bandwidth, variable output power, and variable sensitivity. The architecture consists of both analog and digital components which work together to achieve the desired operating results: multiple modes, multiple bands, and variable sensitivity and gain.

In one embodiment, the receiver architecture consists of a radio frequency (RF) splitter connected to the output of a duplexer or antenna switch. The RF splitter has two output paths, each of which are coupled to one of a pair of polyphase switched capacitor finite impulse response (FIR) filters which preferably operate exactly 90 degrees out of phase from each other. In other words, one of the filters implements an implicit Hilbert transform. The mixing function is preferably implemented as a part of the polyphase decimating (subsampling) filter. Front-end low noise, high sensitivity amplification may or may not be incorporated into the filter technology. The polyphase decimating switched capacitor filter simultaneously filters and downsamples the input radio frequency signal to a significantly reduced bandwidth enabling simplified and reduced rate analog-to-digital conversion for baseband processing.

In another embodiment, the receiver architecture consists of a mixer stage after the RF splitter followed by a polyphase decimating filter implemented with switched capacitor technology. The polyphase decimating switched capacitor filter simultaneously filters and downsamples the input radio frequency signal to a significantly reduced bandwidth enabling simplified and reduced rate analog-to-digital conversion for baseband processing.

In another embodiment, the receiver architecture consists of an RF splitter followed by a polyphase decimating filter implemented with switched capacitor technology. The polyphase decimating switched capacitor filter simultaneously filters and downsamples the input radio frequency signal to a significantly reduced bandwidth enabling simplified and reduced rate analog-to-digital conversion in a baseband processor. A slower speed mixer follows the switched capacitor polyphase decimating filter to provide tuning adjustments. Alternatively, the mixing could be implemented digitally at this stage following analog-to-digital conversion of the signal output by the filter.

In yet another embodiment of the present invention, the receiver architecture consists of a low-noise amplifier with several variable gain stages and one to several sigma-delta modulators. The sigma-delta modulators simultaneously bandlimit, translate, and sample the radio frequency signal into a baseband signal. The baseband signal is processed by a digital signal processor, a field programmable gate array, or an application specific integrated circuit which converts the baseband signal to properly decoded and formatted information bits.

The transmitter architecture preferably consists of a baseband processor for digital-to-analog converting and encoding input digital information bits to create an output baseband signal that is coupled to a transmitter. The transmitter then converts the baseband signal into an RF signal. The transmitter preferably includes a single mixer and programmable oscillator. The radio frequency is preferably amplified with a single gain stage followed by a power amplifier.

The present invention is primarily for use in wireless (over-the-air) digital communications. The inventive architecture provides flexibility to accommodate multiple air interfaces with variable bandwidths and variable types of modulation formats. Because of this flexibility, it is possible to reduce the architecture to a single economical integrated circuit for the entire mobile data radio. The architecture is flexible enough to accommodate any type of data modulation format and any type of air interface. The architecture also does not require redundancy of front-end radio frequency components, which is typical in current state-of-the-art radio frequency architectures.

The steps in a preferred receiver process according to the present invention are as follows:

| | |
|---|---|
| Step 1: | A radio frequency signal is received from an |
| | antenna by a receiver RF front-end. |
| Step 2: | Depending on the method used, the signal received from the |
| | antenna may be amplified using one or more variable gain stage |
| | low-noise amplifiers. |
| Step 3: | The radio frequency signal is translated to a baseband |
| | signal. This is accomplished by coupling the RF signal to an |
| | RF splitter which splits the RF signal in two. Each of these |
| | split signals is coupled to a programmable variable bandwidth |
| | polyphase digital filter to provide bandlimiting corresponding |
| | to the modulation scheme and air interface being used. A |
| | programmable oscillator in a direct digital synthesis and |
| | control (DDS) circuit is set to the appropriate mixing frequency |
| | and is used to provide complementary control of the operation |
| | of these programmable, variable bandwidth polyphase |
| | digital filters. |
| Step 4: | Digital information bits are extracted from the bandlimited |
| | baseband signal in a baseband processor. |

The steps in the transmitter process according to the present invention are as follows:

| | |
|---|---|
| Step 1: | Information bits are modulated into a waveshaped baseband |
| | signal by a baseband processor. |
| Step 2: | The waveshaped baseband signal is directly converted to |
| | a radio frequency signal using a programmable oscillator |
| | and analog mixer. |
| Step 3: | The radio frequency signal is coupled to an antenna for |
| | over-the-air transmission of the signal. |

### BRIEF DESCRIPTION OF THE DRAWINGS

The forgoing aspects and the attendant advantages of the present invention will become more readily apparent by reference to the following detailed description, when taken in conjunction with the accompanying drawings, wherein:

FIG. 1 is a block diagram of a prior art wireless transceiver architecture.

FIG. 2 is a block diagram of tranceiver architecture according to a preferred embodiment of the present invention.

FIG. 3A shows a receive section where the mixing (or heterodyne) operation is built into the filtering process according to a preferred embodiment of the present invention, while FIG. 3B illustrates the functionality of this filtering process.

FIG. 4A shows a receive section suitable for an alternate embodiment of the present invention wherein the heterodyne operation is performed prior to the filtering operation, while FIG. 4B illustrates the functionality of this filtering process.

FIG. 5A shows a receive section suitable for another alternate embodiment of the present invention wherein the heterodyne operation is performed after the filtering operation while FIG. 5B illustrates the functionality of this filtering process.

FIG. 6A shows a preferred embodiment of a polyphase filter which incorporates heterodyne operation for simultaneous filtering, tuning and downconversion for the quadrature signal component according to the present invention, while FIG. 6B illustrates the detailed operation of this filter.

FIG. 7 shows an alternative embodiment of a polyphase filter which incorporates heterodyne operation for simultaneous filtering, tuning and downconversion for the in-phase signal component according to the present invention, while FIG. 6B illustrates the detailed operation of this filter.

FIG. 8A illustrates a block diagram of a discrete time delay, while FIG. 8B shows a switched capacitor implementation of this unit delay operation according to the present invention.

FIG. 9 shows the clocking waveform for a switched capacitor implementation of a unit delay operation according to the present invention.

FIG. 10A illustrates a finite impulse response filter cell, while FIG. 10B shows a switched capacitor implementation of a finite impulse response filter cell of FIG. 10A for one sample of the input signal according to the present invention.

FIG. 11 shows the clocking waveform for a switched capacitor implementation of a finite impulse response cell for one sample of the input signal according to the present invention.

FIG. 12 shows a transceiver architecture according to another embodiment of the present invention wherein the receiver section uses sigma-delta modulators to process the RF signal.

### DETAILED DESCRIPTION OF THE INVENTION

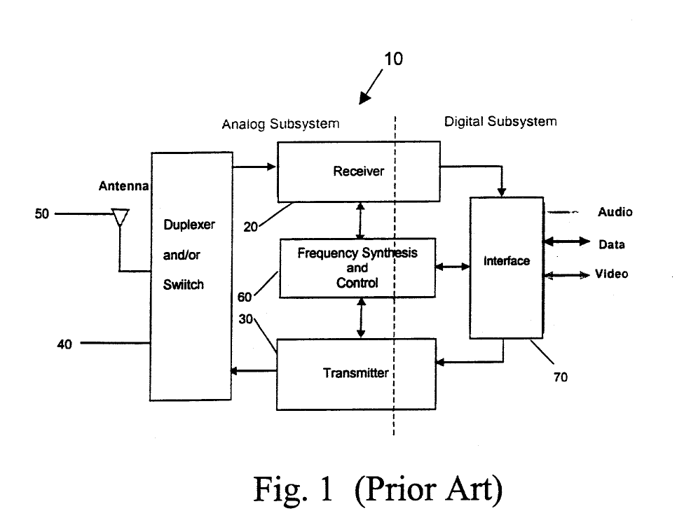

A modem generic transceiver architecture is shown in block diagram form at 10 in FIG. 1. This architecture typically includes analog and digital subsystems. The dividing line between these subsystems depends on the architecture, and can be configured in a variety of ways.

The transceiver 10 includes a receiver block 20 and a transmitter block 30 coupled to an antenna 50 via a duplexer and/or switch 40. A frequency synthesis and control block 60 creates the appropriate mixing frequencies for the receiver and transmitter sections. This is also accomplished through a variety of means. One technique uses a purely analog approach consisting of a Colpitts oscillator design based on a single transistor with feedback and driving resonator. Another technique uses a purely digital approach where a ROM lookup table containing cosine and/or sine values is fed from by a phase accumulator. The output is converted to an analog signal at sufficiently high frequency. Other approaches, including hybrid approaches, can be used for the driving frequency generation.

The receiver block 20 consists of one of several known methods for converting a radio frequency signal to a baseband signal. The receiver block 20 contains a multi-stage low-noise amplifier closest to the antenna. This allows a weak or strong antenna signal to be received at the appropriate level for a mixing stage also contained within receiver block 20. The mixing stage consists of at least one mixer element which converts the radio frequency to either an intermediate frequency or to a baseband frequency. The receiver 20 also contains a variable bandwidth filter stage which bandlimits the intermediate frequency signal and/or the baseband signal to the correct frequency for the data demodulator under the control of the frequency synthesis and control block 60. The receiver 20 typically finally contains a baseband processor including a data demodulator for extracting information bits from the modulated waveforms in the baseband signal. The output of receiver block 20 is coupled to an interface 70 for output to an external device to which the transceiver 10 is connected.

The transmitter block 30 consists of a mixing circuit and variable gain stage. The mixing circuit is fed from a programmable oscillator in the frequency synthesis and control block 60 and the modulated data from interface 70. The output is connected to a power amplifier which feeds an antenna through a duplexer or antenna switch.

The present invention comprises an architecture for a complete, programmable, mobile radio data transceiver/modem that has frequency agility, variable bandwidth, variable output power and variable sensitivity. The architecture consists of both analog and digital components which work together to achieve the desired results, i.e., multiple modes, multiple bands, and variable sensitivity and gain.

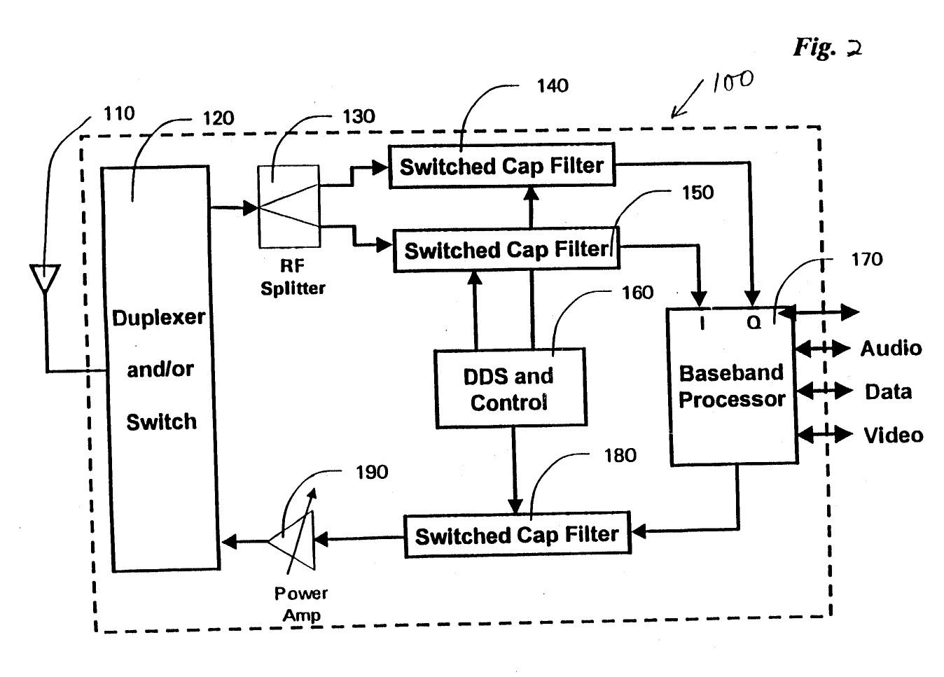

The preferred embodiment of the transceiver/modem architecture according to the present invention is illustrated at 100 in the block diagram of FIG. 2. The transceiver 100 consists of all elements necessary to process a radio frequency signal down to information bits and all necessary elements to convert information bits into a radio frequency signal. The radio frequency signal is received by an antenna 110. The antenna 110 is connected to a duplexer or radio frequency switch 120. For the receiver block function, the radio frequency signal duplexer or switch is connected to a radio frequency (RF) splitter 130 where the signal is split preferably into two identical components at exactly one-half the power. Each split radio frequency signal is connected to switched capacitor filters 140 and 150 which contain the functionality necessary for conversion, bandlimiting and gain management. A direct digital synthesis and control block 160 drives the switched capacitor filters with appropriate clock phases which are used to drive the switching of capacitors inside the switched capacitor filters. The direct digital synthesis and control block also is capable of operating the transmit function. After the radio frequency signal has been downconverted, bandlimited, and sampled, it is then passed into the baseband processor 170 for additional fine tuning, filtering, data demodulation, and error correction in order to obtain accurate information bits. The information bits are then available be sent over various other formats and/or interfaces.

The receiver section performs direct envelope sampling of the radio frequency signal. The signal envelope, which is an analytic signal represented by in-phase and quadrature (I and Q) components, is the best signal to perform digital signal processing upon once the signal has been sufficiently bandlimited so that it does not swamp the signal processor's capabilities.

For the transmitter block, information bits are data modulated in the baseband processor 170 and sent to the switch capacitor transmit filter 180 which simultaneously performs frequency conversion, filtering and gain adjustment to a radio frequency signal. The radio frequency signal is amplified with a power amplifier 190 and sent to through the duplexer or radio frequency switch 120 to the antenna 110 for radio frequency transmission.

If the apparatus is hooked up in the manner shown in FIG. 2, then a true software defined radio frequency transceiver can be achieved with good isolation between the receiver and transmitter due to the lack of any analog oscillators. Only clock noise from switching contributes to the noise level in the system. This can be easily filtered in the baseband processor 170 if the sampling ratio between the switched capacitor filter 140 and 150 and the final bandwidth developed by the baseband processor 170 is large enough.

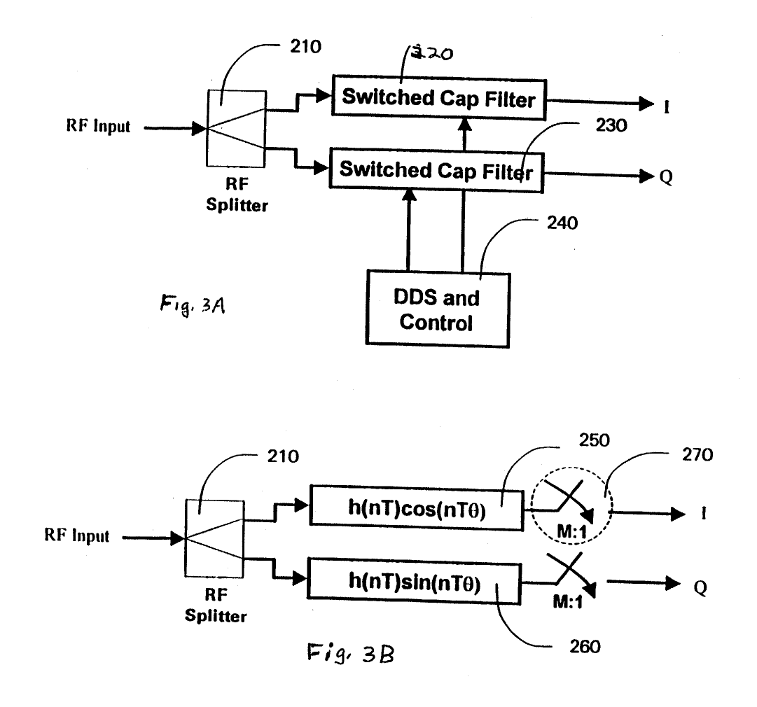

The receiver downconverter section is illustrated in FIGS. 3A and 3B. As seen in FIG. 3A, the radio frequency (RF) downconverter consists of an RF splitter 210 which separates the RF signal into two independent paths. The switched capacitor filter 220 processes the in-phase signal component. The switched capacitor filter 230 processes the quadrature signal component. A direct digital synthesizer and control circuitry 240 controls the receiver downconverter switched capacitor filters in such a way so that the signal is both bandlimited (filtered) and tuned to the desired band. The functions illustrated by the switched capacitor downconversion filters are illustrated in FIG. 3B by boxes 250 through 270. In the in-phase filter 250, h(nT)cos(nTθ) represents a passband converted narrowband filtering function in discrete time format. The filter impulse response, h(nT), is implemented as a polyphase decimator. The decimation function 270 does not need to be integer (it can be fractional). The only difference between the operation of the in-phase filter 250 and the quadrature filter 260 is a 90 degree phase shift between the two filters. Thus, a Hilbert transform, in addition to filtering and downconversion is implied by filter 260.

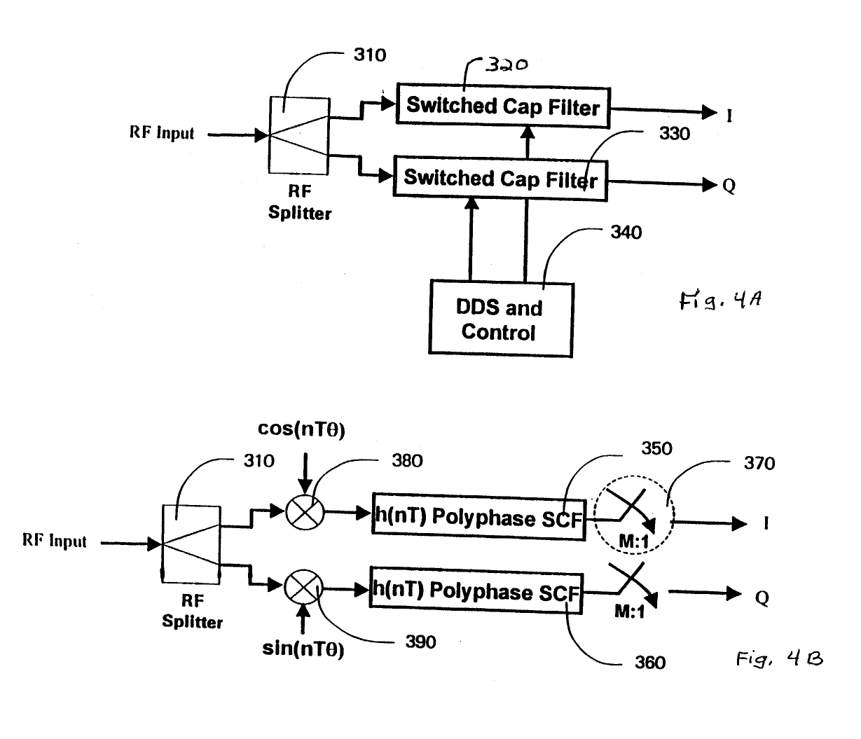

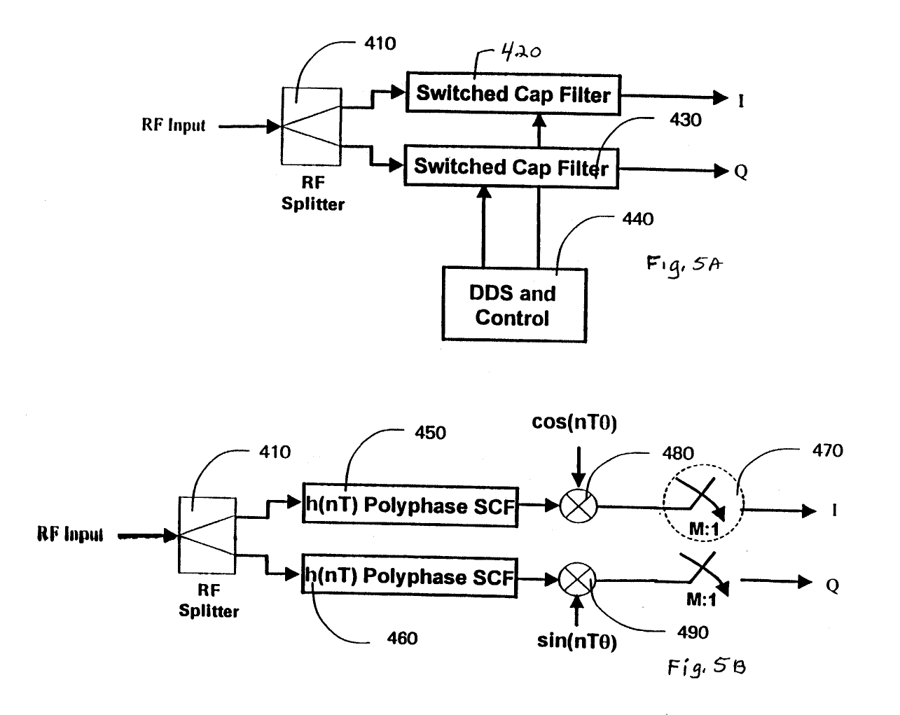

FIGS. 4 and 5 illustrate alternative approaches to tuning. In FIGS. 4A and 5A, the elements are the same as in FIG. 3A but re-labeled to correspond to FIGS. 4 and 5. As seen in FIGS. 4B and 5B, respectively, after splitting 310/410, the two signal paths are either mixed with an in-phase mixing component (oscillation) 380 and a quadrature mixing component (oscillation) 390 or bandlimited 450 and 460. The in-phase and quadrature switched capacitor polyphase downconverter filters 350/450 and 360/460 are identical in this case. Both filters 350/450 and 360/460 perform the bandlimiting function only. Rate decimation 370/470 occurs following both filters after the signal is sufficiently bandlimited. When bandlimiting occurs first, as illustrated by FIG. 5B, the mixing operation 480 and 490 follow bandlimiting and could possibly follow rate reduction 470 depending upon the required resolution.

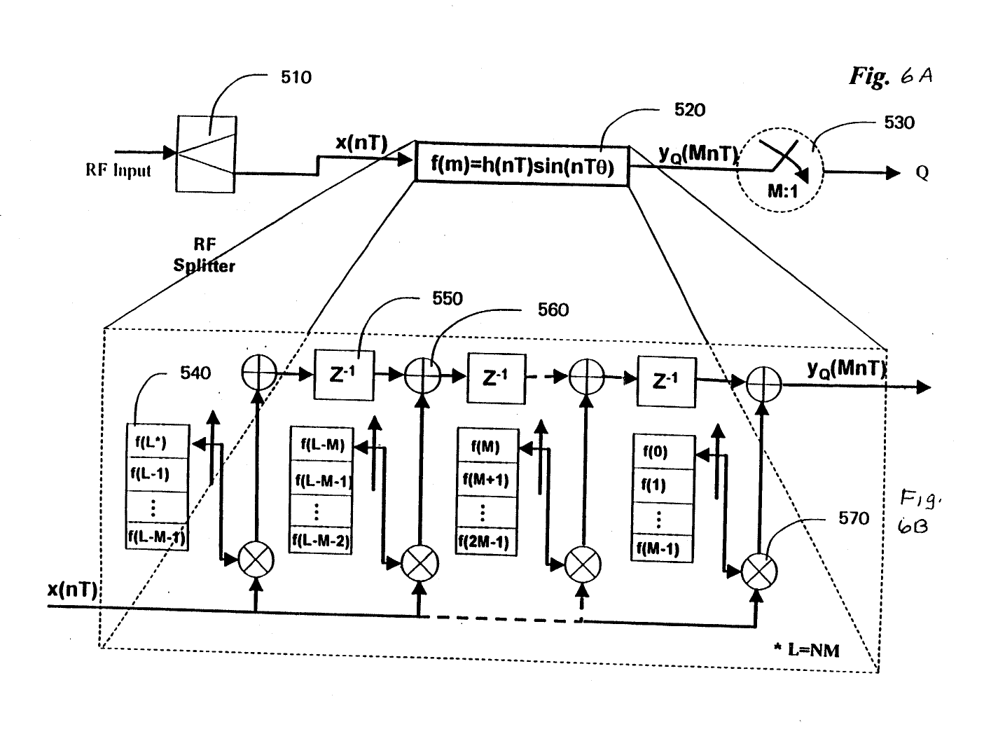

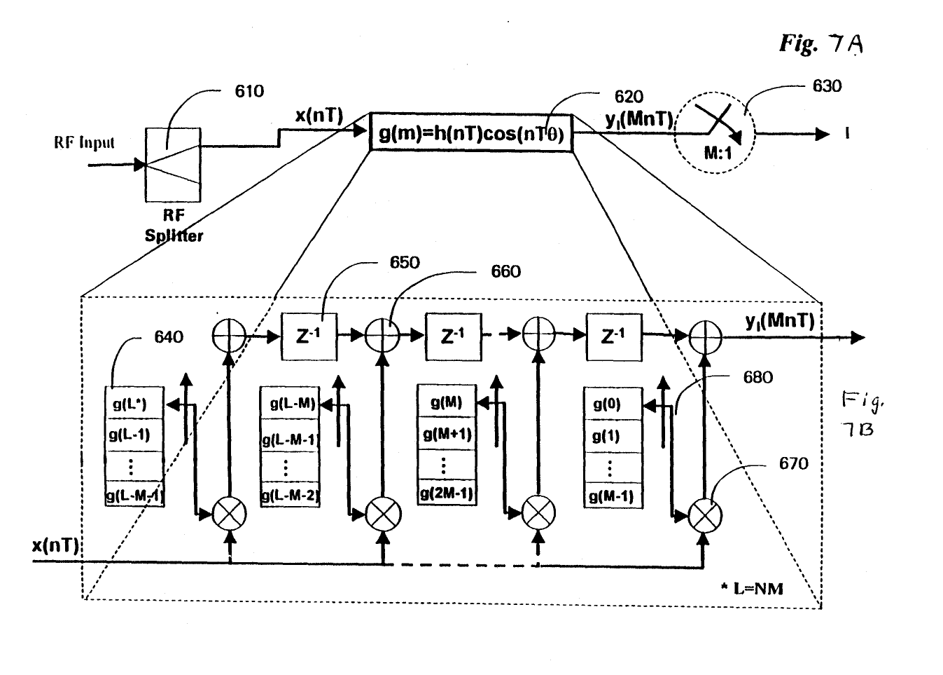

Alternative preferred embodiments of a polyphase filter according to the present operation are shown in FIGS. 6 and 7. As seen in FIGS. 6A and 7A, the RF signal goes through the splitter 510/610 and is processed by in-phase and quadrature switched capacitor polyphase tuner and downconverter filters 520 and 620. Downsampling 530/630 occurs at the output of the filters 520 and 620. The detailed operation of filters 520 and 620 is shown in the breakout drawings of FIGS. 6B and 7B, respectively. The radio frequency signal, represented by x(nT) to illustrate the discrete time nature of the signal processing involved, is processed by a parallel set of switched capacitor arrays which perform finite impulse response (FIR) filtering on the signal. The switched capacitor arrays effect the operations illustrated in the breakout. The signal, x(nT), is multiplied by a cyclic coefficient 540 with a multiplier 570 and then summed with a summer 560 and finally delayed by a delay element 550. There are a total of L coefficients represented by the filter. The L coefficients are broken out into M coefficients per stage and N stages of filters in order to provide an adequate filtering length.

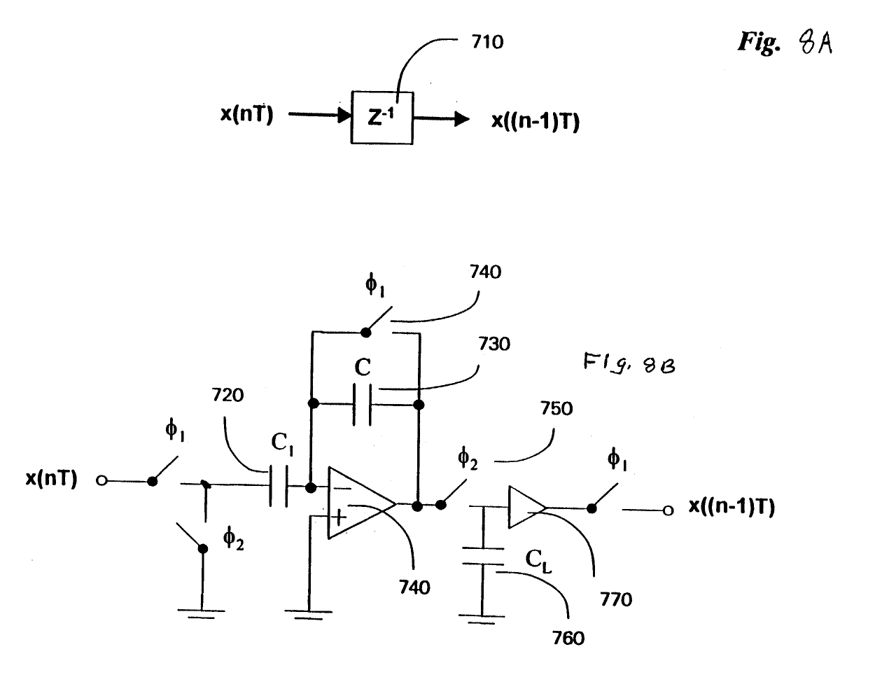

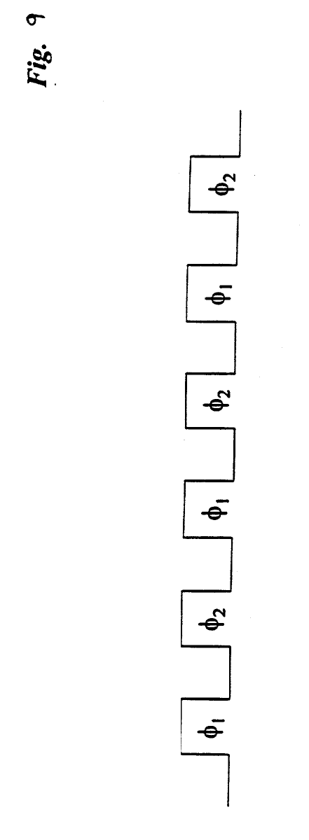

The delay elements represented in the filters of FIGS. 6 and 7 are illustrated in FIG. 8 as implemented in switched capacitor technology. The discrete time delay 710 shown in FIG. 8A can be accomplished as seen in FIG. 8B with the use of an operational amplifier 740, capacitors 720 and 730 and switches 740 and 750 followed by a load capacitor 760 and signal buffer 770. The switches are opened and closed according to the waveform pattern shown in FIG. 9. The signal energy is accumulated in capacitor C₁ 720 on the first phase of the clock cycle. In the second phase it is released into the load capacitor 760 through the feedback capacitor 730. On the next clock phase, the signal energy propagates through the buffer 770 and is output, thus effecting a total delay of one clock cycle.

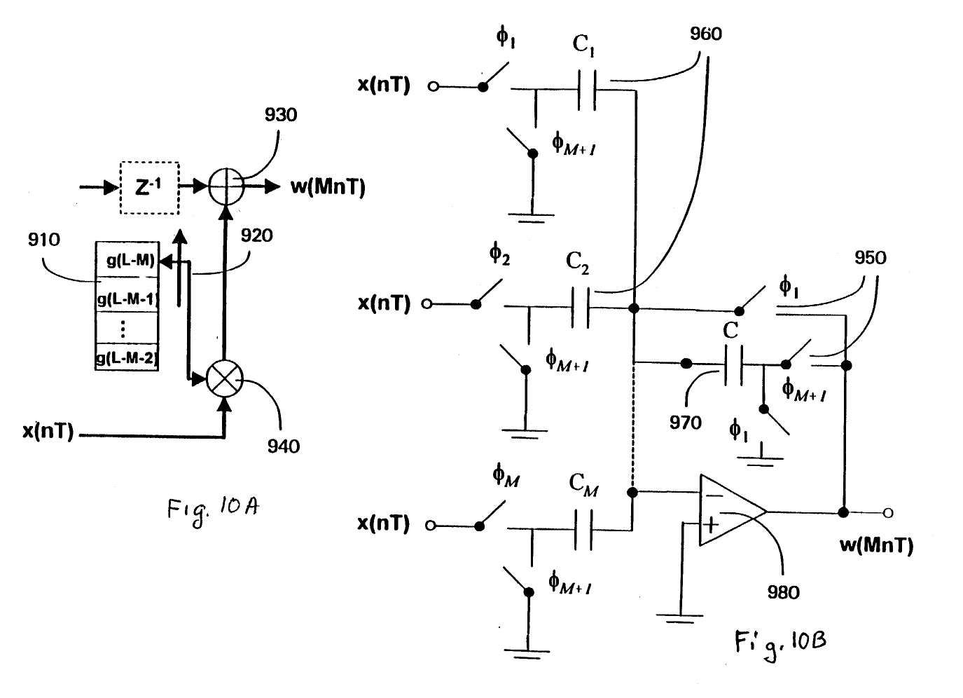

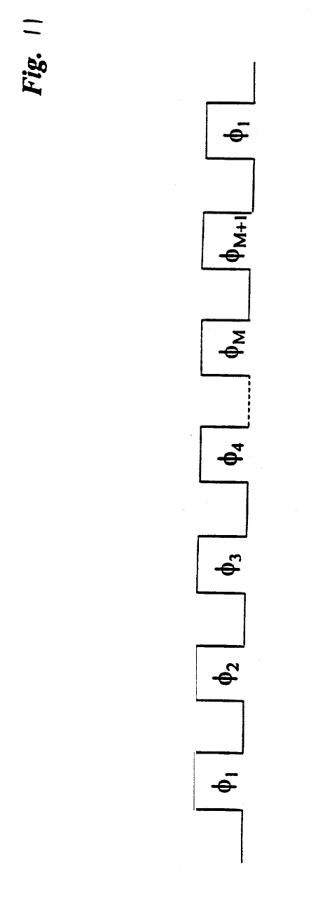

The core operation of the finite impulse response (FIR) filter is illustrated in the diagram of FIG. 10. The signal from any stage is propagated into the multiplier 940 and multiplied by a coefficient obtained from a table of coefficients 910 which is switched with a commutator 920 and finally added to the delayed signal with an adder 930 to produce the output for one stage of the FIR filter. FIG. 10B illustrates a switched capacitor implementation of this filter stage. A polyphase filter can be efficiently implemented using switching capacitors 960 (which approximate resistive components from the switching action), switches (which are transistors) 950 and an operational amplifier 980 configured in summing mode. The clocking waveform shown in FIG. 11 is a waveform that illustrates the action of this stage of the switched capacitor polyphase FIR filter. The signal x(nT) is assumed to be held stable for the duration of this waveform. On the first phase of the clock, signal energy is accumulated on capacitor C₁ 960 and held. On the next phase of the clock, signal energy is accumulated on capacitor C₂ 960 and held. The process continues through capacitor C_{M}. This stage mimics the operation of the multiplier 940 with the filter coefficients 910. On the M+1 phase of the clock cycle, the total stored energy supplied by the signal and stored by the capacitors C₁ through C_{M} is delivered to the main feedback capacitor C970. The addition of all the capacitors' stored energies is effected by the operational amplifier 980 and delivered to the load w(MnT) which is now a reduced rate signal of M times less than the rate of the signal x(nT). This action mimics the summing operation 930 of a FIR filter in the diagram.

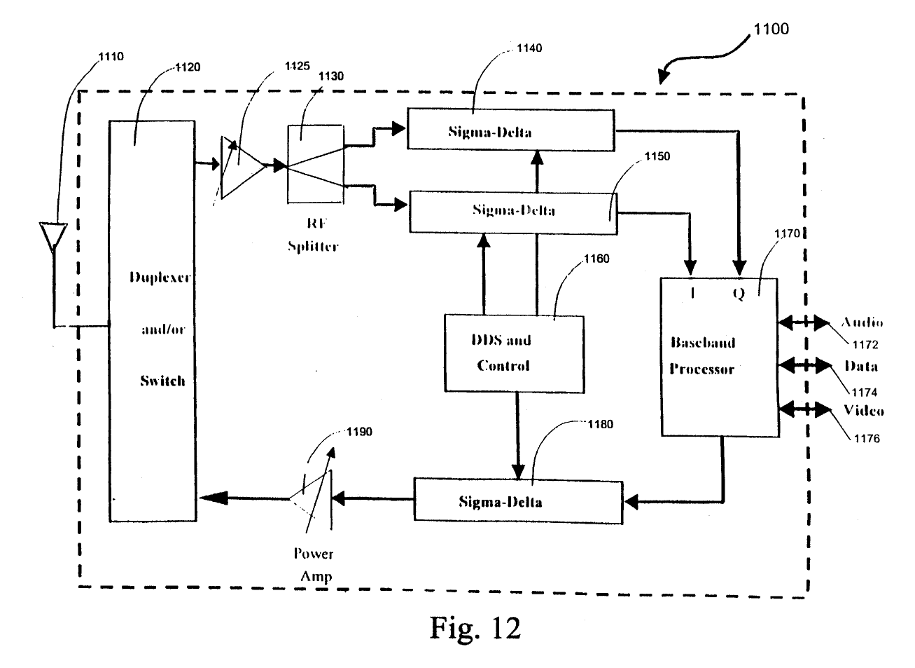

In another embodiment, shown in FIG. 12, the transceiver 1100 includes a low-noise receive amplifier LNA 1125 with several variable gain stages followed by an RF splitter 1130 and one 1140 to several 1150 sigma-delta modulators. The sigma-delta modulators simultaneously bandlimit, translate, and sample the radio frequency signal into a baseband signal. The baseband signal is processed by a digital signal processor 1170 which can be implemented by a field programmable gate array or an application specific integrated circuit. The DSP 1170 converts the baseband signal to properly decoded and formatted information bits such as 1160 provides the required frequency references to the sigma-delta modulators. The transmit portion of the transceiver 1100 takes in the audio 1172, data 1174, and/or video 1176 signals into a DSP baseband processor 1170 which feeds the sigma-delta modulator 1180 which converts the baseband signal directly to radio frequency. The output of the sigma-delta modulator is fed to a variable power amplifier 1190. The duplexer or antenna switch 1120 takes the transmit signal from the power amp 1190 and feeds the antenna 1110. The duplexer 1120 also takes the received signal from the antenna 1110 and feeds the LNA 1125.

An inventive radio frequency transceiver architecture has no analog oscillators or mixers. Because there are no analog oscillators or mixers present, non-linear artifacts which inhibit radio performance are no longer a factor in the design considerations. It has high isolation between receiver and transmitter allowing integration of the entire software radio onto a single integrated circuit. A new method for radio frequency transmission of a data modulated baseband signal using switched capacitor filtering is also described. It allows for the complete integration of multiple fimctions in the transmit chain into a single complex device. The functions that are integrated include gain control, up-conversion (mixing), and interpolative bandlimiting (or smoothing). These three functions are achieved within the same switched capacitor filter. This integration of functions allows several devices to be eliminated from the transmit chain. It also allows for the complete integration of multiple functions in the receive chain into a single complex pair of devices. The functions that are integrated include gain control, down-conversion (mixing), and bandlimiting (decimation and filtering). This integration allows several devices to be eliminated from the receive chain.

The embodiments of the present invention described above are illustrative of the present invention and are not intended to limit the invention to the particular embodiments described. Accordingly, while the preferred embodiment of the invention has been illustrated and described, it will be appreciated that various changes can be made therein without departing from the spirit and scope of the invention.

What is claimed is:

1. A frequency agile variable bandwidth radio frequency (RF) transceiver comprising:
an RF input/output stage for input of an RF signal from an antenna during a receive mode and for output of an RF signal to an antenna during a transmit mode:
an RF splitter for splitting the input RF input signal into a first RF signal and a second RF signal:
a direct digital synthesis and control (DDS) circuit including a programmable oscillator;
an in-phase component polyphase filter for filtering and bandlimiting said first RF signal under the control of said DDS circuit to generate a first output bandlimited signal;
a quadrature component polyphase filter for filtering said second RF signal under the control of said DDS circuit to generate a second output bandlimited signal; and
a baseband processor for demodulating said first and second output bandlimited signals to generate an output digital signal comprising a plurality of data bits.

2. The RF transceiver of claim 1, wherein said in-phase component polyphase filter comprises a first switched capacitor filter, and wherein said quadrature component polyphase filter comprises a second switched capacitor filter.

3. The RF transceiver of claim 2, wherein said first and second switched capacitor filters operate 90 degrees out of phase from each other, and wherein each said switched capacitor filter includes a mixer element which operates to convert the RF signal to a baseband frequency.

4. The RF transceiver of claim 1, further comprising a third polyphase filter coupled to said baseband processor and said DDS for modulating digital data bits in a transmit mode to generate an output RF signal for coupling to an antenna.

5. The RF transceiver of claim 4, wherein said third polyphase filter comprises a third switched capacitor filter.

6. A frequency agile variable bandwidth radio frequency (RF) transceiver comprising:
an RF input/output stage for input of an RF signal from an antenna during a receive mode and for output of an RF signal to an antenna during a transmit mode:
an RF splitter for splitting the input RF input signal into a first RF signal and a second RF signal:
a direct digital synthesis and control (DDS) circuit including a programmable oscillator;
an in-phase component polyphase switched capacitor filter for filtering and bandlimiting said first RF signal under the control of said DDS circuit to generate a first output bandlimited signal;
a quadrature component polyphase switched capacitor filter for filtering said second RF signal under the control of said DDS circuit to generate a second output bandlimited signal;
a mixer coupled to the output of each said switched capacitor filter and operative to tune the output of said respective filter; and
a baseband processor for demodulating said first and second output bandlimited and tuned signals to generate an output digital signal comprising a plurality of data bits.

7. A frequency agile variable bandwidth radio frequency (RF) transceiver comprising:
an RF input/output stage for input of an RF signal from an antenna during a receive mode and for output of an RF signal to an antenna during a transmit mode:
an RF splitter for splitting the input RF input signal into a first RF signal and a second RF signal:
a direct digital synthesis and control (DDS) circuit including a programmable oscillator;
a first sigma-delta modulator coupled to said first RF signal to bandlimit, translate, and sample said first RF signal under the control of said DDS circuit to generate a first output bandlimited signal;
a second sigma-delta modulator coupled to said second RF signal to bandlimit, translate, and sample said second RF signal under the control of said DDS circuit to generate a second output bandlimited signal; and
a baseband processor for demodulating said first and second output bandlimited and tuned signals to generate an output digital signal comprising a plurality of data bits.

8. A method for generating a frequency agile variable bandwidth radio frequency (RF) transceiver comprising the steps of:
detecting an RF signal from an antenna during a receive mode and for output of an RF signal to an antenna during a transmit mode:
splitting the input RF input signal into a first RF signal and a second RF signal:
filtering and bandlimiting said first RF signal using an in-phase component polyphase filter to generate a first output bandlimited and tuned signal;
filtering said second RF signal using a quadrature component polyphase filter to generate a second output bandlimited and tuned signal; and
demodulating said first and second output bandlimited and tuned signals to generate an output digital signal comprising a plurality of data bits.
